(19) United States
(12) Patent Application Publication
(10) Pub. No.: US 2026/0119777 A1
(43) Pub. Date: Apr. 30, 2026

(54) Method for Parasitic Extraction Using Spatial Localization

(71) Applicant: GenChip.AI Inc., Sunnyvale, CA (US)

(72) Inventors: Sreekar Bathula, San Jose, CA (US); Eric Panning, Portland, OR (US)

(21) Appl. No.: 19/376,591

(22) Filed: Oct. 31, 2025

Related U.S. Application Data
(60) Provisional application No. 63/714,754, filed on Oct. 31, 2024.
(60) Provisional application No. 63/714,761, filed on Oct. 31, 2024.
(60) Provisional application No. 63/714,793, filed on Oct. 31, 2024.
(60) Provisional application No. 63/714,797, filed on Oct. 31, 2024.
(60) Provisional application No. 63/714,796, filed on Oct. 31, 2024.
(60) Provisional application No. 63/714,773, filed on Oct. 31, 2024.

(51) Int. Cl. G06F 30/398; G06F 30/31

(52) U.S. Cl. CPC G06F 30/398; G06F 30/31

(57) ABSTRACT

A method and system for parasitic extraction in semiconductor layouts using spatial localization and point reduction, thereby improving efficiency of predictive models for identifying parasitic capacitance in electronic circuit design. Candidate physical layouts are generated from electrical design. Transistors and wiring are spatially modeled as three-dimensional structures. Geometrical points are identified from the three-dimensional structures being modeled and used as nodes in a neural network. A subset of the nodes is selected, and the subset is further limited to a limited region surrounding the given node to be evaluated. Nodes can have weighting based on relative geometrical position. Parasitic extraction is performed on the limited number of nodes for efficient evaluation of candidate layouts.

### CROSS-REFERENCE TO RELATED APPLICATIONS

This application claims the benefit of and priority to U.S. Provisional Patent Application Ser. No. 63/714,754 entitled “Method for Estimating Parasitic Capacitance Using Spatial Localization,” 63/714,761 entitled “Method and System for Estimating Parasitic Capacitance Using Localized Weighting and Federated Learning Model,” 63/714,793 entitled “Method for Transistor Order Placement Using Graph Neural Network Recursive Model,” 63/714,797 entitled “Method for Transistor Layout Generation Using Graph Neural Network Recursive Model,” 63/714,796 entitled “Method for Transistor Layout Design Checking Using Reinforcement Learning,” and 63/714,773 entitled “Method For Transistor Layout Design Using 3D Model Representation in Latent Space,” all of which were filed on Oct. 31, 2024 and which applications are expressly incorporated herein by reference in their entirety.

### BACKGROUND OF THE INVENTION

The present disclosure generally relates to electronic design automation for the design and manufacture of integrated circuits and microelectronics.

Electronic design automation (EDA) includes software tools for designing electronic systems such as integrated circuits. With semiconductor chips having billions of components or more, computer-aided tools are essential for the logical design, physical design, and manufacturing process. Integrated circuit design includes many steps, typically beginning with a system specification. Following system specification, several logical design steps can be completed based on that specification including register transfer level design, functional verification, timing simulation, and netlist generation. After logical design, physical design steps can be executed to generate a physical layout of the integrated circuit. There are many physical design steps including partitioning, floor planning, placement, clock tree synthesis, and signal routing, among others. After a physical layout is verified, then an integrated circuit can be fabricated using the physical layout generated from EDA tools.

During the physical design process of an integrated circuit, a significant variable to generating an acceptable design that meets logical constraints and system specifications is parasitic capacitance. Parasitic capacitance is the unwanted, yet unavoidable, capacitance that exists between conductive parts separated by an insulator of an electronic circuit. Parasitic capacitance can cause the behavior of chip components to depart from ideal performance. As circuits are continually scaled and the separation between conductive components shrinks, parasitic capacitance becomes a significant problem and a limiting factor in physical chip design.

### SUMMARY OF THE INVENTION

Identifying or estimating parasitic capacitance in a given physical layout design of an integrated circuit is a time-intensive task. Computer-aided processing to analyze a proposed design to identify parasitic capacitance at points in a standard cell and signal routing network considers all contributing features in the proposed design. This can take hours to complete, and that is for just one proposed design. To evaluate large numbers of proposed layouts then requires significant time, which delays chip design.

Techniques herein include improved predictive models for identifying parasitic capacitance in electronic circuit design using localization techniques of layout features. Such techniques can significantly improve accuracy and efficiency of predicting parasitic capacitance effects within integrated circuits. Such techniques include identification and selection of particular input variables or features that represent underlying characteristics of a circuit layout being evaluated. This enables accelerated modeling of parasitic capacitance with high precision. Localization techniques focus on refining predictive models by incorporating spatial information and considering the proximity of circuit components, thus enhancing the granularity and fidelity of the predictions. Such techniques can significantly reduce parasitic evaluation processing time of various proposed layouts, as well as optimizing the reliability of electronic circuit designs.

In one example embodiment, a method for parasitic extraction includes receiving a graphic design system (GDS) file of a very large-scale integration (VLSI) integrated circuit from an electronic design automation tool. The GDS file including a first layout of the VLSI integrated circuit. The first layout specifies a set of transistors with at least a first wiring layer interconnecting the transistors. The method includes spatially modeling, by a processing device, the transistors and wiring structures from the first layout as three-dimensional structures. The method includes identifying geometrical points, from the three-dimensional structures being modeled, as nodes for use in a neural network. The method also includes selecting, by the processing device, a subset of the nodes relative to a given node in the first layout for evaluation, the subset of nodes located within a predetermined region surrounding the given node. The method includes performing, by the processing device, parasitic extraction of the given node in the first layout using the neural network and limiting nodes contributing to parasitic capacitance to the subset of the nodes within the predetermined region surrounding the given node. The method also includes outputting, by the processing device, parasitic extraction data to a memory store, the parasitic extraction data corresponding to the GDS file of the VLSI integrated circuit.

In one example embodiment, a system comprises a memory storing instructions, and a processing device, coupled with the memory and configured to execute the instructions. Alternatively, a non-transitory computer readable medium comprises stored instructions, which when executed by a processing device, cause the processing device to execute the instructions. The instructions, when executed, cause the processing device to receive a graphic design system (GDS) file of a very large-scale integration (VLSI) integrated circuit from an electronic design automation tool. The GDS file includes a first layout of the VLSI integrated circuit. The first layout specifies a set of transistors with at least a first wiring layer interconnecting the transistors. The instructions, when executed, cause the processing device to spatially model the transistors and wiring structures from the first layout as a three-dimensional structure. The instructions, when executed, cause the processing device to identify geometrical points from the spatial model as nodes. The instructions, when executed, cause the processing device to select a subset of the nodes relative to a given node in the first layout for evaluation. The instructions, when executed, cause the processing device to perform parasitic extraction of the given node in the first layout by limiting nodes contributing to parasitic capacitance to the subset of the nodes and further limiting nodes contributing to parasitic capacitance to nodes within a predetermined region surrounding the given node. The instructions, when executed, cause the processing device to output parasitic extraction data, corresponding to the GDS file of the VLSI integrated circuit, to a memory store. Other embodiments of this aspect include corresponding computer systems, apparatus, and computer programs recorded on one or more computer storage devices, each configured to perform the actions of the methods.

### BRIEF DESCRIPTION OF DRAWINGS

This disclosure will be understood more fully from the detailed description below and from the accompanying figures of embodiments of the disclosure. The figures are used to facilitate understanding of embodiments of the disclosure and do not limit the scope of the disclosure to these specific embodiments. The figures are not necessarily drawn to scale.

FIG. 1 illustrates an autoencoder system herein.

FIG. 2 is a block diagram of a parasitic capacitance estimation system herein.

FIG. 3 is a flow diagram for parasitic capacitance estimation according to one embodiment.

FIG. 4 is a flow diagram for parasitic capacitance estimation according to one embodiment.

FIG. 5 is flow chart of example embodiments herein for parasitic extraction.

FIG. 6 is flow chart of example embodiments herein for parasitic extraction.

FIGS. 7A-7D illustrate mesh densities in modeling.

FIGS. 8A-8C are perspective views of example wiring layouts to illustrate parasitic extraction techniques herein.

FIG. 9 depicts a representative diagram of an example computer system in which embodiments of the present disclosure may operate.

### DETAILED DESCRIPTION

Disclosed herein are improved methods and systems for parasitic extraction including predicting or estimating parasitics for candidate physical layouts of an integrated circuit or portion thereof with increased efficiency. Such techniques can significantly reduce processing time and requirements to evaluate a set of circuit and wiring designs. Techniques here include local focus or local limitation as well as component selection and weighting to limit parasitic extraction calculations to a smaller data set or region. Accordingly, with such techniques processing time can be dramatically reduced enabling more layout evaluations in a shorter period. Techniques herein can be used from cell to circuit including standard cell placement/route as well as signal delay for both 2D and 3D parasitic extraction and optimization.

In one general example, a model engine is used to model in 2D space or 3D space. Parasitic extraction can be limited by inputs or a reduced amount of inputs are considered, which can be reduce relative to conventional inputs. Alternatively, parasitic extraction is limited to evaluation between certain components or points instead of a predictive analysis over an entire set of transistors. For example, parasitic capacitance at a given point location can be estimated between a net and also between corners of the nets or where there is a via present.

Processes herein include feature engineering in which physical features are evaluated to identify relative importance for inclusion, exclusion and weighting. Accordingly, some features or physical aspects of a circuit design will be considered when generating parasitic extraction (that is, included in parasitic capacitance calculations), while other features will be excluded from consideration. Additionally, among features selected to be considered, a weighting or relative importance value can be assigned to modify respective values (such as by using a coefficient) for parasitic extraction.

For given physical design components, values can be assigned at various nodes of shapes such as corners, edges, midpoints, and so forth, with each component having a corresponding value. In some embodiments herein, corner components (for example) can be included for parasitic capacitance calculations while middle components or points along a wire segment can be excluded. Parasitic extraction can be executed more quickly with fewer values considered compared to conventional parasitic extraction evaluations.

In addition to omitting some nodes (such as midpoints) from capacitance modeling, proximity can also be used to identify values to include or exclude in the model used for parasitic extraction. With capacitance modeling of a physical layout design, all components of the physical layout design can affect parasitic capacitance of a given point in the design to one degree or another. Nevertheless, it is recognized herein that as components have an increased distance from a location being considered, their respective effect or contribution to parasitic capacitance becomes less significant. Accordingly, for more efficient modeling, values beyond a particular distance, radius, or component count can be excluded from parasitic extraction. For example, this can be set by linear distance in terms of nanometers from a given point, or limited to adjacent standard cells, or limited to a closest number of points/values identified for consideration, such as the closest 20 nodes/components or 30 or 50 or so on. As can be appreciated, there are various options for proximity limiting.

In some embodiments, an input or inputs can be a mesh or netlist or other combination of logical designs. Portions of the design can be modeled as polyhedrons or cuboids or other geometric three-dimensional shapes or regions. What can then be considered for parasitic extraction are geometrical corners and other points on and in the polyhedron. Middle points of the region can also be considered. The process mesh is a physical representation of the structure. This can include a description of the geometrical nodes as well as their relationship to adjacent geometrical nodes. Such modeling can include modeling the three-dimensional structure and projecting to the two-dimensional structure.

For example, a 2D metal design can be extruded to a 3D model or representation. With such modeling, a polyhedron or other 3D region can be identified to find relevant corners or points. These corners can be labeled on the GDS (graphic design system) as points of interest. Alternatively, to restrict to 2D space for simplicity, the input can be a 2D polygon. The edges of the polygon, and middle points of the polygon represent corners of interest of the nets. These corners of interest are sometimes called hot corners. Although, in a spatially local area, all of corners and middle points can affect resistance and capacitance, to achieve efficiencies herein, some, or all, of the middle points can be removed from calculations. Whether to include or exclude midpoints can be based on length of metal wire and/or proximity to adjacent metal wires. After this removal, the process herein calculates resistances and capacitances between the end nodes in the limited region. The capacitance values are sufficiently accurate to evaluate initial candidate designs, and processing time is greatly reduced. By way of a non-limiting example, this could be executing one calculation instead of ten calculations or a hundred calculations or thousands of calculations. As can be appreciated, reducing the calculations by one or more orders of magnitude can significantly increase efficiency enabling evaluation of more candidate layouts in a shorter time.

Spatial information can be used to assign weighting to the geometrical nodes being included in calculations. Adjacent nodes can be assigned a higher weighting value relative to geometrical nodes farther apart or separated by one or more intermediate geometrical nodes. A rigorous calculation would consider every point's effect on parasitic capacitance at all other points in the layout. While this whole design calculation is useful, it is time consuming. With techniques herein, many physical layout options/permutations can be considered/quickly, being evaluated for parasitic capacitance values. This can include estimating parasitic capacitance of one net to another net, or from one wire connected to a standard cell to another wire in that standard cell. For example, methods herein can be used to quickly evaluate millions of proposed designs and permutations of wiring devices. Rigorous calculations of millions of designs could take months or longer conventionally, thus significantly delaying circuit development. Techniques herein can reduce the evaluation of millions of designs from, for example, months to days or shorter. From these millions of evaluations, a subset of candidate layouts can be identified having best capacitance performance. This subset can then be subject to more rigorous, conventional calculations to identify a highest performance design, or a design that is closest to meeting design constraints from among the top candidates. With the efficient parasitic capacitance estimation herein, the full permutation space for layouts can be explored against given design rules. Various metrics can be used to determine which permutations are superior, depending on individual design objectives for a given integrated circuit. Then further vetting can be done.

In some embodiments, a self-attention network can be used to process inputs to systems and methods herein. This can be a reduced form of a circuit. This circuit can be represented using a GDS file, a GDT file, or OASIS file, or other extension types of layout representation. GDS, GDT, and OASIS are all file formats used in the design of integrated circuits (ICs). GDSII is a binary file format that's often used to exchange IC data, while OASIS is a binary file format used to specify data structures for photomask production. Models herein are configured to represent a 2D structure in an efficient manner to quickly make an approximation for parasitic extraction. Note that certain parts of a given physical design are 2D from a top-down view as in 2D transistors, but 2D transistors when fabricated are, of course, three-dimensional structures. Accordingly, height of metal lines and transistors and material choice becomes important.

Conventionally, parasitic extraction of a given design can take hours. This could be seven or ten or more hours for one design depending on how complicated the design is. With techniques herein, modeling of parasitic capacitance for a given design can be reduced to minutes or seconds. This is a significant improvement, especially when it is desired for many thousands or millions of designs to be considered. Such techniques herein can be especially useful to quickly narrow a large pool of proposed layout designs. The techniques herein can quickly identify significant problems and quickly validate designs to find functional designs and best designs from the functional designs. This can be used to quickly narrow possible designs to a small number of candidate designs, which can then be evaluated to generate parasitic extraction data using more rigorous and time-consuming techniques to identify a best design meeting design constraints.

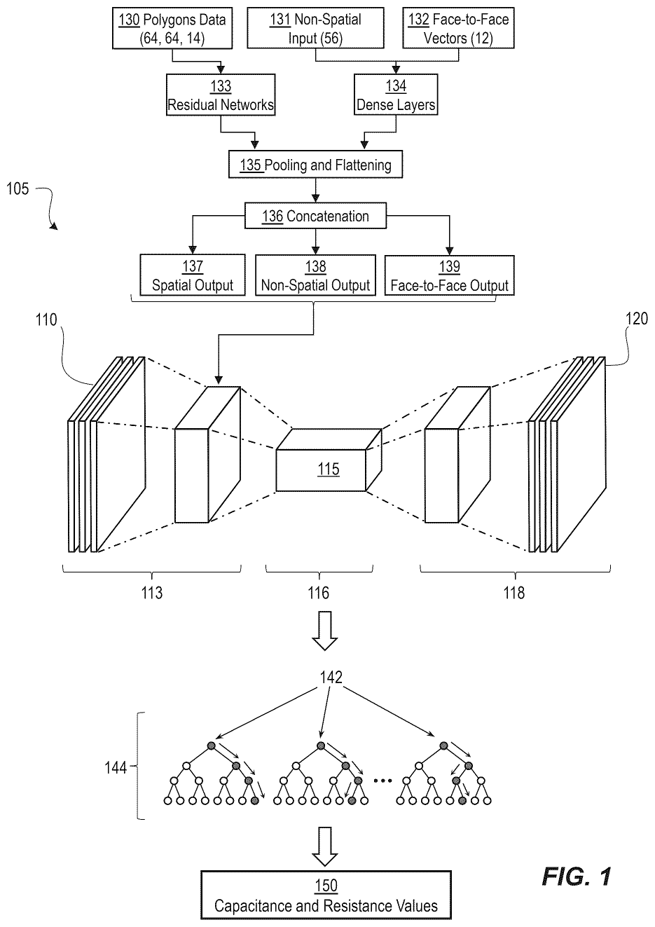

Techniques herein include using an advanced autoencoder model embedded with a residual network convolutional neural network architecture. This autoencoder model receives input, condenses the input into a latent space representation, and then feeds this representation into a random forest regression model to predict capacitance values. Polygon data is convolved using the residual network, and linear transformations are performed on the face-to-face value vectors and non-spatial data, thereby providing an effective solution. FIG. 1 illustrates.

FIG. 1 shows a parasitic extraction system 105 for processing data to estimate capacitance and resistance values. The parasitic extraction system 105 can be implemented by a system that processes various inputs through a series of computational layers to produce outputs related to spatial, non-spatial, and face-to-face vectors. The parasitic extraction system 105 includes components such as polygons data 130 as input to residual networks 133. Non-spatial input 131 and face-to-face vectors 132 feed into dense layers 134. Non-spatial input can include numerical or categorical data without a spatial component. Face-to-face vectors can represent relationships between different spatial elements. Next pooling and flattening 135 is executed. This step reduces the dimensionality of the data while preserving features for further processing. Next concatenation 136 is executed, which combines spatial and non-spatial features into a unified representation. This step prepares the data for output generation. Outputs include spatial output 137, non-spatial output 138, and face-to-face output 139. These three outputs, as well as input GDS, feed into encoder 113. A latent space representation 115 (latent space representation model), is used to transform inputs into output GDS using decoder 118. There is a bottleneck 116, however, to complete the transformation. Instance 142 of a candidate layout in latent space representation can be processed using a random forest 114 to create decision trees to generate capacitance and resistance values 150.

Techniques herein also include an advanced routing mechanism that converges designs to one GDS layout. This routing model uses a learning mechanism in a parasitic capacitance predictive model, which is trained on all possible permutations. Parasitic extraction data is used to determine a best possible permutation among the GDS files generated.

The parasitic capacitance predictive model herein uses a reinforcement learning agent to determine a single best layout corresponding to a particular design specification. Layout results can even relax rules specified earlier in the DRC (Design Rule Check). This process takes a netlist as an input and then generates a single layout. The generated layout can be varied in the rules specified and might be the best in terms of PPAC calculations. The parasitic capacitance predictive model herein is able to generate faster results compared to conventional techniques, including results returned ten times faster or more. Using simulated annealing further provides better performance. The parasitic extraction modeling engine or separate modeling module can model physical characteristics of wires to how the wires would behave electrically after an annealing process is executed. The annealing process can create subtle shifts in metal shape and structure, affecting electrical properties.

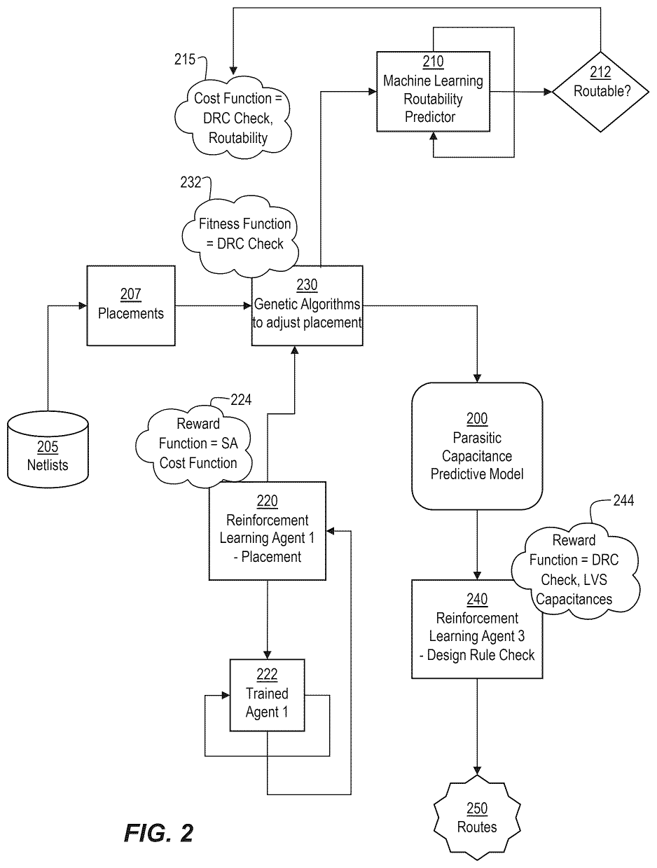

FIG. 2 is a flow diagram illustrating a schematic arrangement of systems and methods herein for parasitic extraction data generation as well as reinforcement learning to continually improve parasitic extraction models herein. FIG. 2 shows a system for evaluating candidate physical layouts of circuits and updating algorithms using reinforcement learning. The system begins with Netlists 205, which provide the initial logical circuit design inputs. These netlists feed into Placements 207, where the system determines potential physical arrangements of the circuit components.

Placements 207 are sent to genetic algorithm 230, which adjusts placement. Adjustments can be made using fitness function 232, which can include a design rule check. The genetic algorithm 230 explores various placements and can communicate with machine learning routability predictor 210, which assesses the routability of these placements. The predictor can use a cost function 215, which includes Design Rule Check (DRC) and routability metrics, to evaluate the placements. If the placements are deemed routable, as determined at step 212, then the process continues. Otherwise, adjustments are made to improve routability, which can include continued iteration from the machine learning routability predictor until finding a routing configuration meeting cost functions.

Genetic algorithms 230 or a model used for genetic algorithms 230 can be trained using trained agent1 222 as well as a reinforcement learning agent1 220. The reinforcement learning agent1 220 focuses on optimizing the placement process. This agent uses a reward function 224, which can incorporate a simulated annealing (SA) cost function, to guide the learning of reinforcement learning agent1 220. The agent iteratively refines the approach of reinforcement learning agent1 220, resulting in trained agent1 222 that can produce improved placements, which in turn improves the genetic algorithm 230 or provides input used by genetic algorithm 230.

Genetic algorithms have been used to optimize problems, such as financial modeling, by mimicking a process of natural selection to purposely evolve to an optimal result. Example genetic algorithms can function or be executed using several sub steps, with the objective of determining positions of transistors in a layout by optimizing multiple constraint objectives as specified. This can include subdivisions of continuous layout optimization problems and discrete layout optimization problems. Additional ways of categorizing layout optimization problems as an equal-area problem, unequal area problem, Quadratic Assignment Problem (QAP) and Quadratic Set Covering Problem (QSCP) can be optionally used.

The genetic algorithm can be considered as randomized heuristics, not dependent on prior knowledge of various features of the domain whereas it depends on the randomized choice of operators. The main steps used in the genetic algorithm—selection, crossover, and mutation—are used to create the future generation from the current generation. Selection rules select parents, that are used to create a next generation. Crossover is used to define rules of combining parents to generate children. Mutation is used to apply random changes to some of the individuals from the new generation.

The input for the genetic algorithm can also include a desired fitness score and a maximum number of generations, with the output being a fitness strategy. Sub steps can include generating an initial population, setting population score to zero, set generation number to zero, while the population score is less than a desired score or generation number, which is less than a maximum generation. Then get a sorted population, population score, and best individual score. Perform selection and crossover, sort the population, perform a mutation, then increment a generation number.

The genetic algorithm 230 then generates many candidate layouts, making the candidate layouts accessible to parasitic capacitance predictive model 200. The Parasitic Capacitance Predictive Model 200 analyzes the selected placements to estimate parasitic capacitance values. This model can provide electrical performance of the proposed layouts. Reinforcement learning agent3 240 performs a Design Rule Check (DRC) on the layouts, using a reward function 244 that considers DRC, layout versus schematic (LVS) checks, and capacitance values. This agent ensures that the layouts meet all necessary design constraints.

The final output of the system is routes 250 as well as placement adjustments, which are optimized physical layout paths for the circuit or at least improve physical layout paths. These routes are the result of the combined efforts of machine learning, genetic algorithms, and reinforcement learning, thereby providing efficient and effective circuit design.

Note that techniques herein can provide quick evaluation of various layout designs by refraining from considering all input variables. One advantage of such techniques and systems is that millions of possible designs can be quickly evaluated to find a relatively small subset or short list of candidate layouts. After reducing the candidate layouts from millions to a few or to tens of candidate layouts, the remaining layouts can be fully evaluated with convention techniques that evaluate all input variables. With a relatively small number of layouts to fully evaluate, the secondary evaluation can be completed within a shorter time to accelerate chip development.

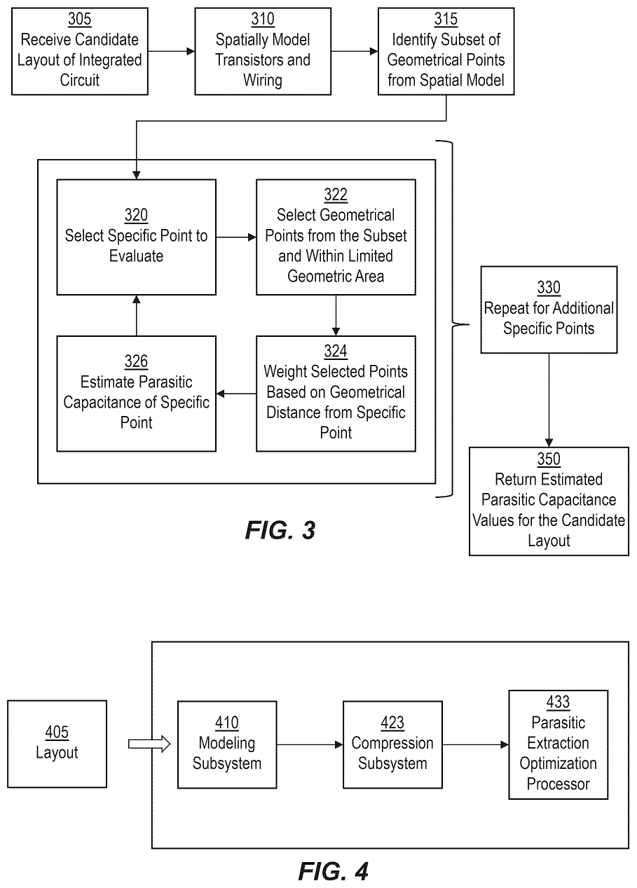

FIG. 3 shows a flow chart illustrating a method for quickly evaluating multiple candidate physical layouts of a given logical circuit design while FIG. 4 shows basic architecture layout for increased efficiency in processing. Process begins with receiving a candidate layout of an integrated circuit 305. This layout serves as the initial input for the evaluation process. The next step involves spatially modeling the transistors (transistor devices) and wiring 310. This spatial modeling transforms the layout into a format that allows for detailed analysis of the geometrical relationships between components. Following the spatial modeling, the method identifies a subset of geometrical points from the spatial model 315. This subset represents the points of interest that will be further analyzed for parasitic capacitance estimation.

The process then selects a specific point to evaluate 320. This selection focuses the analysis on a particular point within the layout, allowing for targeted evaluation of parasitic effects. Once a specific point is selected, the method selects geometrical points from the subset and within a limited geometric area 322. This step narrows down the points considered in the analysis to those within a defined proximity to the specific point, improving the evaluation process. The selected points are then weighted based on their geometrical distance from the specific point 324. This weighting assigns greater importance to points closer to the specific point being evaluated, reflecting their more significant impact on parasitic capacitance. With the weighted points, reduced number of points, and limited geometrical distance, the method estimates the parasitic capacitance of the specific point 326. This estimation provides a quantitative measure of the parasitic effects at the selected point, contributing to the overall evaluation of the layout. This process is repeated for additional specific points 330, repeating the evaluation steps to cover multiple points within the layout until a given candidate layout is evaluated to generate parasitic extraction data. This iterative approach enables comprehensive analysis across the entire candidate layout. The method returns the estimated parasitic capacitance values for the candidate layout 350. These values provide results of parasitic performance of the layout, aiding in the selection and optimization of design configurations.

FIG. 4 is a simplified schematic showing embodiments using a compression subsystem. The compression subsystem 423—and associated processors or engines—can be an improved computing system and/or algorithm that operates faster compared to conventional parasitic extraction systems, in part because less work is performed by the parasitic capacitance optimization processor 433. The compression subsystem 423 receives input from modeling subsystem 410, which models a candidate physical layout or logical layout such as received as layout 405.

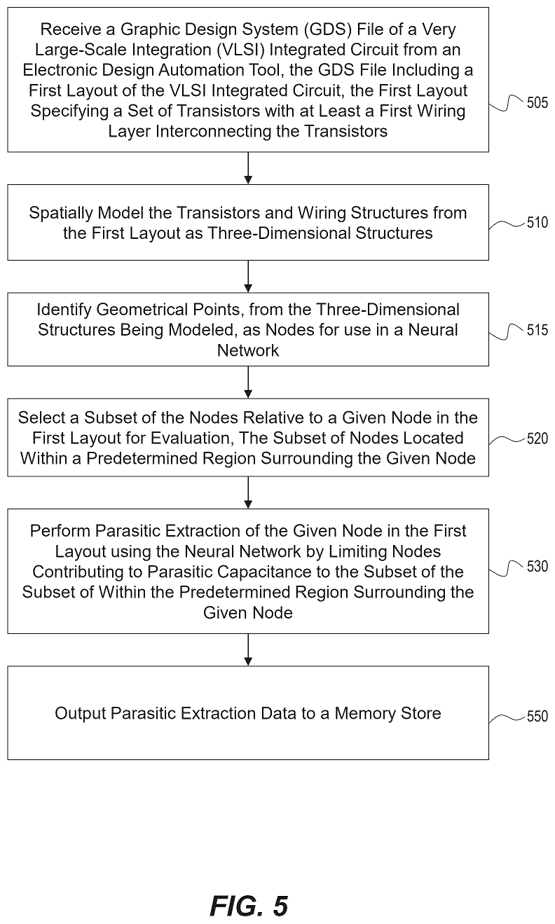

FIG. 5 is a flow chart of example embodiments herein. In step 505, the process begins with receiving a graphic design system (GDS) file of a very large-scale integration (VLSI) integrated circuit from an electronic design automation tool. The graphic design system file includes a first layout of the VLSI integrated circuit. The first layout specifies a set of transistors with at least a first wiring layer interconnecting the transistors. Additional wiring layers can be included. Having active devices plus interconnected wiring enables subsequent parasitic extraction. The layout serves as the foundational input for the subsequent steps in the parasitic extraction process.

Next, in step 510, the system spatially models the transistors and wiring structures from the first layout as three-dimensional structures. This spatial modeling transforms the two-dimensional layout into a three-dimensional representation with geometrical points, which can include corners, midpoints and line segments. All geometries, including wire thickness, separation routes, length, and other attributes can contribute to parasitic capacitance. The three-dimensional structure provides a detailed model of the layout, from which points, for parasitic extraction, can be identified.

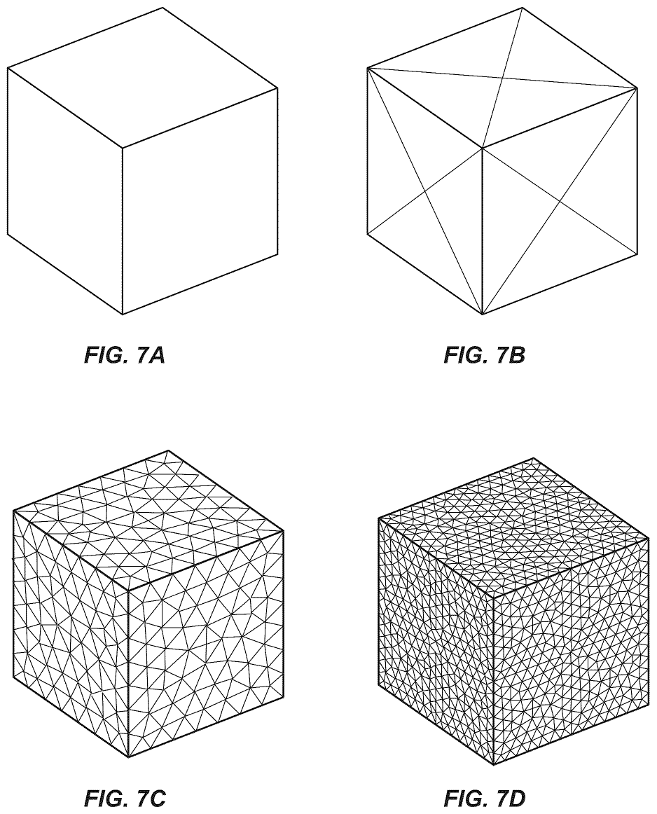

In step 515, the process identifies geometrical points, from the three-dimensional structures being modeled, as nodes for use in a neural network. These nodes represent specific locations within the three-dimensional structure that are relevant for, or contributory to, parasitic extraction. Note that the system can be set to identify a particular density of points based on an input or mesh or as specified by an operator. A mesh density of a model results in a particular number of geometrical points identified. FIG. 7 illustrates various mesh densities. FIG. 7A shows an example region as a cube, but any geometry can be modeled based on a layout. FIG. 7B shows a mesh with low density, FIG. 7C shows a mesh with medium density, and FIG. 7D shows a mesh with high density. A particular mesh density can be selected based on design objectives as well as other factors such as number of candidate layouts to evaluate. If several thousand candidate layouts are to be evaluated, then a higher mesh density can be selected. If, however, millions of candidate layouts are to be evaluated, then a lower mesh density can be used. Thus, a particular mesh density can be based on available or designated processing time and number of candidate layouts.

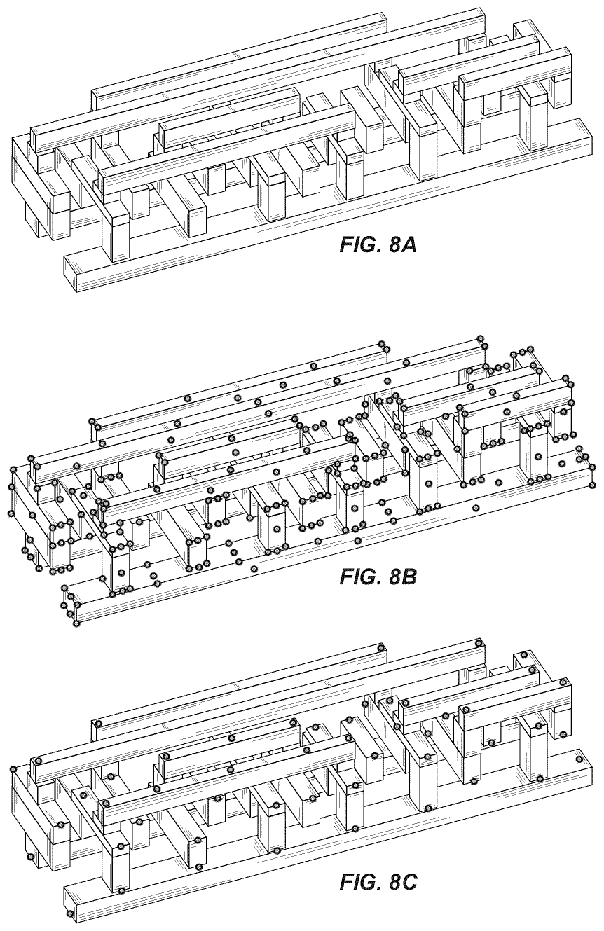

FIG. 8 then illustrates geometric point modeling and node selection. FIG. 8A is a perspective view of an example physical layout of wiring for a given circuit, circuit element, or standard cell or portion thereof. This active device is modeled as a three-dimensional structure or portion thereof. FIG. 8B shows identified nodes from geometrical points based on a given design density. Note that corners, surfaces, and edges can have many nodes or geometric points. FIG. 8C then shows a subset of the nodes selected for use in parasitic extraction. Accordingly, fewer visible points are displayed in this illustrative example. Limiting parasitic extraction to a subset of nodes can reduce accuracy of overall parasitic extraction, but this limitation also reduces processing time thereby increasing a number of candidate layouts that can be analyzed within a given time. As can be appreciated, reducing the number of nodes considered has a tradeoff on processing time.

Following the identification of nodes or available nodes based on a density or similar input, in step 520 the system selects a subset of the nodes relative to a given node in the first layout for evaluation. This selection process can narrow down the nodes considered in the analysis to those within a defined proximity to the given node. By limiting the evaluation to a subset of nodes, the process improves the analysis, reducing computational complexity and focusing on the most relevant areas for parasitic extraction. In other words, nodes considered for parasitic extraction calculations can be limited to within a particular region surrounding a node, and also limited by excluding some of those nodes from the particular region.

The subset of nodes can be selected using various techniques including a self-attention network. In some embodiments middle points of wiring structure lines are excluded from the subset of nodes. Training of this self-attention network can be performed using manual selection of example transistor models, and/or can use instructions identifying selection criteria such as percentage of points, types of points, relative location of points, et cetera.

In step 530 the system then performs parasitic extraction of the given node in the first layout using a neural network by limiting nodes contributing to parasitic capacitance to the subset of the nodes and further limiting nodes contributing to parasitic capacitance to nodes within a predetermined region surrounding the given node. This step can include calculating the parasitic capacitance by considering only the selected nodes within a specific region, enhancing the efficiency of the extraction process. The predetermined region surrounding the given node can be a polyhedron with geometrical points from the three-dimensional structure that is modeled. In some embodiments the polyhedron can be defined by a linear distance (such as in nanometers) from a given geometrical point or node. In some embodiments, the polyhedron can be defined as a standard cell or number of adjacent standard cells, or a simple sphere or rectangular cuboid. Nodes in the given predetermined region can have a weighting or relative value based on distance from a given node or location within the predetermined region. Performing parasitic extraction can include using a parasitic capacitance predictive model that uses a neural network to predict the parasitic capacitance based on the weighted variables.

In step 550, the system outputs parasitic extraction data, corresponding to the GDS file of the VLSI integrated circuit, to a memory store. This output includes the results of the parasitic extraction process, providing data for further analysis and optimization of the integrated circuit design. The stored data can be used for subsequent evaluations or as input for additional design iterations. Parasitic extraction can be performed for a plurality of nodes from the first layout, wherein outputting parasitic extraction data to the memory store includes parasitic extraction data from the plurality of nodes. Additional embodiments can include generating a visual representation of the parasitic extraction data for the first layout. This enables users to view the best candidate layouts with accompanying parasitic extraction data for verification. Other embodiments can return or display a ranked list of candidate layouts based on a parasitic extraction data score, which in turn can be based on various parasitic capacitance parameters. The result can be, for example, a list of top candidate layouts or candidate layouts having a better parasitic capacitance score compared to other candidate layouts. In other words, a ranked list of GDS files can be displayed as a short list of the best layouts based on parasitic extraction data. The benefit is that the system herein can evaluate thousands or millions or more of candidate layouts, in a relatively short time, to narrow layouts to a relatively small group of layouts. This reduced list of candidate layouts can then be evaluated with more thorough parasitic extraction analysis techniques.

Additional embodiments can include using a reinforcement learning agent to update a parasitic extraction model used to perform the parasitic extraction. The parasitic extraction model can include simulating annealing when performing the parasitic extraction. Simulated annealing involves temperature and materials modeling to identify how modifications to metal affect capacitance of physical structures.

Such techniques can be embodied as a method executed fully or partially using a computing device. Other embodiments include a system comprising a memory storing instructions and a processing device, coupled with the memory and configured to execute the instructions. The instructions, when executed, cause the processing device to execute the above methods. These instructions can be stored in a non-transitory computer readable medium.

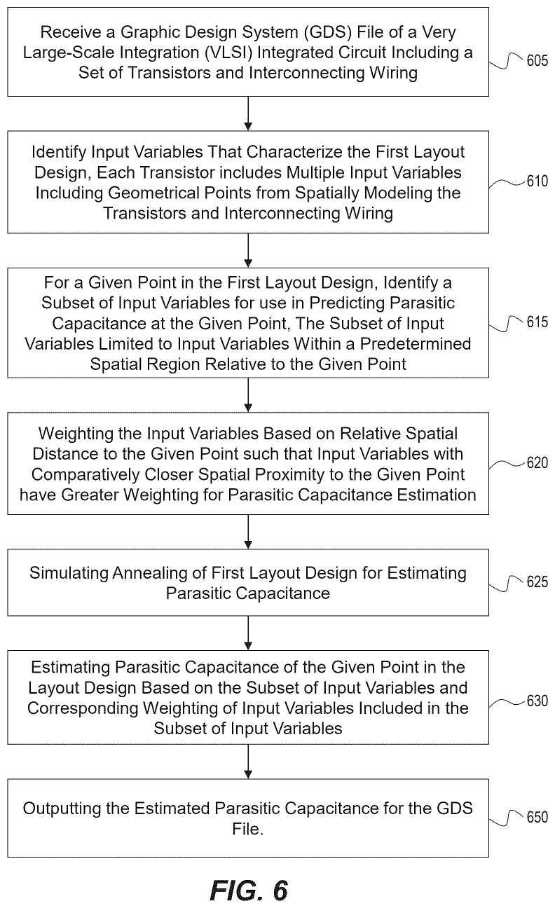

FIG. 6 shows an alternative method for efficiently evaluating candidate physical layouts of an integrated circuit, which can be executed by a system. In step 605, the process begins with receiving a graphic design system (GDS) file of a very large-scale integration (VLSI) integrated circuit first layout design of an integrated circuit, which includes a set of transistors and interconnecting wiring. This initial step includes obtaining the foundational design data necessary for further analysis and evaluation. The initial layout can be obtained from a netlist, GDS file, mesh, or other logical circuit description.

In step 610, the system identifies input variables that characterize the first layout design. Each transistor includes multiple input variables such as geometrical points. The system spatially models the transistors and interconnecting wiring. This identification is helpful for understanding the layout's characteristics and preparing for subsequent analysis. Input variables can include electrical properties of transistors and interconnecting wiring.

For a given point in the first layout design, the system identifies a subset of input variables for use in predicting parasitic capacitance at that point (step 615). The subset of input variables is limited to those within a predetermined spatial region relative to the given point. The predetermined spatial region can be defined by a radius from a given point or other distance measure. The predetermined spatial region can be defined by a number of adjacent transistors to a given point, or by electrical nodes. Or it can be defined by a wire length from a given point. Alternatively, the subset is limited to a predetermined number of geometrical points. In step 620, the system includes weighting the input variables based on their relative spatial distance to the given point. Input variables with comparatively closer spatial proximity to the given point receive greater weighting for parasitic capacitance estimation. This weighting reflects the more significant impact of nearby variables on parasitic effects. Input variables can be excluded such as those corresponding to middle points of interconnecting wiring. Also, weighting of the one or more input variables can be adjusted dynamically based on changes in the layout design.

In step 625, the system simulates annealing of the first layout design to better estimate parasitic extraction data using more realistic modeling. This simulation process helps refine the layout design by considering thermal and material properties, enhancing the accuracy of the capacitance estimation.

Subsequently, in step 630, the system estimates the parasitic capacitance of the given point in the layout design. This estimation is based on the subset of input variables and their corresponding weighting. The process provides a quantitative measure of the parasitic effects at the selected point, contributing to the overall evaluation of the layout. Estimating parasitic capacitance can include using an autoencoder model embedded with a residual network convolutional neural network architecture.

In step 650, the system outputs the estimated parasitic capacitance for the first layout design or the GDS file of the VLSI integrated circuit. This output includes the results of the parasitic capacitance estimation, providing data for further analysis and optimization of the integrated circuit design. The parasitic extraction can then be repeated for many points in a given candidate layout. And then many candidate layouts can be evaluated to generate parasitic extraction data for comparison to identify candidate layouts performing better than other candidate layouts.

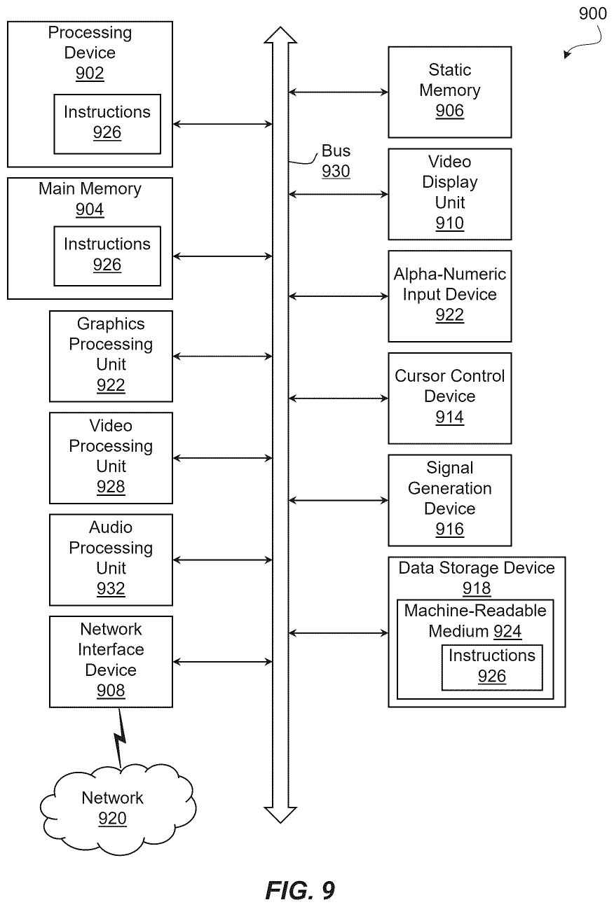

FIG. 9 depicts a representative diagram of an example computer system in which embodiments of the present disclosure may operate.

A storage subsystem of a computer system (such as computer system 900 of FIG. 9) may be used to store the programs and data structures that are used by some or all of the EDA products described herein, and products used for development of cells for the library and for physical and logical design that use the library.

FIG. 9 illustrates an example machine of a computer system 900 within which a set of instructions, for causing the machine to perform any one or more of the methodologies discussed herein, including efficient parasitic extraction and spatial localization in electronic design of an integrated circuit, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The computer system 900 example includes a processing device 902, a main memory 904 (e.g., read-only memory (ROM), flash memory, dynamic random access memory (DRAM) such as synchronous DRAM (SDRAM), a static memory 906 (e.g., flash memory, static random access memory (SRAM), etc.), and a data storage device 918, which communicate with each other via a bus 930.

Processing device 902 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 may also be one or more special-purpose processing devices such as an application specific integrated circuit (ASIC), a field programmable gate array (FPGA), a digital signal processor (DSP), network processor, or the like. The processing device 902 may be configured to execute instructions 926 for performing the operations and steps described herein.

The computer system 900 may further include a network interface device 908 to communicate over the network 920. The computer system 900 also may include a video display unit 910 (e.g., a liquid crystal display (LCD) or a cathode ray tube (CRT)), an alphanumeric input device 912 (e.g., a keyboard), a cursor control device 914 (e.g., a mouse), a graphics processing unit 922, a signal generation device 916 (e.g., a speaker), graphics processing unit 922, video processing unit 928, and audio processing unit 932.

The data storage device 918 may include a machine-readable storage medium 924 (also known as a non-transitory computer-readable medium) on which is stored one or more sets of instructions 926 or software embodying any one or more of the methodologies or functions described herein. The instructions 926 may also reside, completely or at least partially, within the main memory 904 and/or within the processing device 902 during execution thereof by the computer system 900, the main memory 904 and the processing device 902 also constituting machine-readable storage media.

In some implementations, the instructions 926 include instructions to implement functionality corresponding to the present disclosure. While the machine-readable storage medium 924 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 902 to perform any one or more of the methodologies of the present disclosure. The term “machine-readable storage medium” shall accordingly be taken to include, but not be limited to, solid-state memories, optical media, and magnetic media.

Some portions of the preceding detailed description have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be noted, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

1. A method for parasitic extraction, the method comprising:
receiving a graphic design system file (GDS file) of a very large-scale integration (VLSI) integrated circuit from an electronic design automation tool, the graphic design system file including a first layout of the VLSI integrated circuit, the first layout specifying a set of transistors with at least a first wiring layer interconnecting the transistors;
spatially modeling, by a processing device, the transistors and wiring structures from the first layout as three-dimensional structures;
identifying geometrical points, from the three-dimensional structures being modeled, as nodes for use in a neural network;
selecting, by the processing device, a subset of the nodes relative to a given node in the first layout for evaluation, the subset of nodes located within a predetermined region surrounding the given node;
performing, by the processing device, parasitic extraction of the given node in the first layout using the neural network and limiting nodes contributing to parasitic capacitance to the subset of the nodes within the predetermined region surrounding the given node; and
outputting, by the processing device, parasitic extraction data to a memory store, the parasitic extraction data corresponding to the GDS file of the VLSI integrated circuit.

2. The method of claim 1, further comprising:
performing, by the processing device, parasitic extraction of a plurality of nodes from the first layout using the neural network, wherein parasitic extraction for each respective node from the plurality of nodes is performed using a respective subset of nodes within a respective predetermined region surrounding the respective node; and
wherein the parasitic extraction data outputted to the memory store includes parasitic extraction data from the plurality of nodes.

3. The method of claim 2, further comprising:
performing, by the processing device, parasitic extraction of a plurality of nodes from a plurality of layouts received from the electronic design automation tool, each parasitic extraction performed for each layout using subsets of nodes within predetermined regions surrounding given nodes being evaluated; and
wherein the parasitic extraction data outputted to the memory store includes parasitic extraction data from the plurality of layouts.

4. The method of claim 3, further comprising:
displaying at least a portion of the plurality of layouts ranked based on parasitic extraction data corresponding to each layout.

5. The method of claim 1, further comprising: weighting nodes with a contribution value in the predetermined region based on relative distance from the given node.

6. The method of claim 5, wherein the predetermined region surrounding the given node is a polyhedron with geometrical points from one or more three-dimensional structures being modeled.

7. The method of claim 6, wherein the subset of the nodes is selected using a self-attention network.

8. The method of claim 6, wherein selecting the subset of nodes includes excluding middle points of wiring structure lines.

9. The method of claim 1, further comprising using a reinforcement learning agent to update a parasitic extraction model used to perform the parasitic extraction.

10. The method of claim 9, wherein the parasitic extraction model includes simulating annealing when performing the parasitic extraction.

11. A system comprising:
a memory storing instructions; and
a processing device, coupled with the memory and configured to execute the instructions, the instructions when executed cause the processing device to:
receive a graphic design system file (GDS file) of a very large-scale integration (VLSI) integrated circuit from an electronic design automation tool, the graphic design system file including a first layout of the VLSI integrated circuit, the first layout specifying a set of transistors with at least a first wiring layer interconnecting the transistors;
spatially model the transistors and wiring structures from the first layout as three-dimensional structures;
identify geometrical points, from the three-dimensional structures being modeled, as nodes for use in a neural network;
select a subset of the nodes relative to a given node in the first layout for evaluation, the subset of nodes located within a predetermined region surrounding the given node;
perform parasitic extraction of the given node in the first layout using the neural network and limiting nodes contributing to parasitic capacitance to the subset of the nodes within the predetermined region surrounding the given node; and
output parasitic extraction data to a memory store, the parasitic extraction data corresponding to the GDS file of the VLSI integrated circuit.

12. The system of claim 11, wherein the instructions further cause the processing device to:
perform parasitic extraction of a plurality of nodes from the first layout using the neural network, wherein parasitic extraction for each respective node from the plurality of nodes is performed using a respective subset of nodes within a respective predetermined region surrounding the respective node; and
wherein the parasitic extraction data outputted to the memory store includes parasitic extraction data from the plurality of nodes.

13. The system of claim 12, wherein the instructions further cause the processing device to:
perform parasitic extraction of a plurality of nodes from a plurality of layouts received from the electronic design automation tool, each parasitic extraction performed for each layout using subsets of nodes within predetermined regions surrounding given nodes being evaluated; and
extraction data from the plurality of layouts.

14. The system of claim 13, wherein the instructions further cause the processing device to:
return layouts ranked based on parasitic extraction data corresponding to each layout.

15. The system of claim 11, wherein the instructions further cause the processing device to:
weight nodes with a contribution value in the predetermined region based on relative distance from the given node.

16. The system of claim 15, wherein the predetermined region surrounding the given node is a polyhedron with geometrical points from the three-dimensional structure that is modeled.

17. A non-transitory computer readable medium comprising stored instructions, which when executed by a processing device, cause the processing device to:
receive a graphic design system file (GDS file) of a very large-scale integration (VLSI) integrated circuit from an electronic design automation tool, the graphic design system file including a first layout of the VLSI integrated circuit, the first layout specifying a set of transistors with at least a first wiring layer interconnecting the transistors;
spatially model the transistors and wiring structures from the first layout as three-dimensional structures;
identify geometrical points, from the three-dimensional structures being modeled, as nodes for use in a neural network;
select a subset of the nodes relative to a given node in the first layout for evaluation, the subset of nodes located within a predetermined region surrounding the given node;
perform parasitic extraction of the given node in the first layout using the neural network and limiting nodes contributing to parasitic capacitance to the subset of the nodes within the predetermined region surrounding the given node; and
output parasitic extraction data to a memory store, the parasitic extraction data corresponding to the GDS file of the VLSI integrated circuit.

18. The non-transitory computer readable medium of claim 17, wherein the instructions further cause the processing device to:
perform parasitic extraction of a plurality of nodes from the first layout using the neural network, wherein parasitic extraction for each respective node from the plurality of nodes is performed using a respective subset of nodes within a respective predetermined region surrounding the respective node; and
wherein the parasitic extraction data outputted to the memory store includes parasitic extraction data from the plurality of nodes.

19. The non-transitory computer readable medium of claim 18, wherein the instructions further cause the processing device to:
perform parasitic extraction of a plurality of nodes from a plurality of layouts received from the electronic design automation tool, each parasitic extraction performed for each layout using subsets of nodes within predetermined regions surrounding given nodes being evaluated; and
wherein the parasitic extraction data outputted to the memory store includes parasitic extraction data from the plurality of layouts.

20. The non-transitory computer readable medium of claim 19, wherein the instructions further cause the processing device to:
return layouts ranked based on parasitic extraction data corresponding to each layout.
